(19) United States
(12) Patent Application Publication
(10) Pub. No.: US 2005/0136633 A1
(43) Pub. Date: Jun. 23, 2005

(54) Blocking layer for silicide uniformity in a semiconductor transistor

(76) Inventors: William J. Taylor JR., Round Rock, TX (US); David C. Gilmer, Austin, TX (US); Srikanth B. Samavedam, Austin, TX (US)

Correspondence Address: FSI;C/O LALLY & LALLY, L.L.P., P. O. BOX 684749, AUSTIN, TX, 78768-4749, US

(21) Appl. No.: 10/739,684

(22) Filed: Dec. 18, 2003

(51) Int. Cl. H01L 21/4763; H01L 21/3205; H01L 21/44

(52) U.S. Cl. 438/592

(57) ABSTRACT

A semiconductor device and fabrication process includes forming a gate dielectric overlying a semiconductor substrate and a gate electrode overlying the gate dielectric. The gate electrode includes an interface between a first portion of the gate electrode and a second portion of the gate electrode. A silicide is then formed overlying the gate electrode. The presence of the gate electrode interface substantially prevents the silicide from spiking into or through the gate electrode to encroach upon or contact the underlying gate dielectric. Forming the gate electrode may include forming a polysilicon first gate electrode layer and forming an amorphous silicon layer over the polysilicon first gate electrode layer. Forming the second gate electrode layer may include forming a SiGe first sublayer and a polysilicon second sublayer.

### BACKGROUND OF THE INVENTION

1. Field of the Invention

The present invention is in the field of semiconductor fabrication processes and more particularly semiconductor fabrication processes employing a silicide material.

2. Description of Related Art

The use of silicides is a well known technique for improving contact resistance in a semiconductor fabrication process. A silicide is a compound of silicon and another element, typically a metal. Silicides are formed by depositing the metal over a wafer, usually after defining the transistor gate electrodes, implanting the source/drain regions, and forming dielectric spacers on the gate electrode sidewalls. The wafer is heated to react the metal with the silicon. Wherever the depositing metal is in contact with a dielectric, the metal remains unreacted. The unreacted metal is then etched away with a selective etchant. In this manner, the silicide self-aligns to the exposed silicon in the source/drain areas and at the top of the gate electrodes thereby desirably decreasing the resistance of subsequently formed gate and source/drain contacts.

Scaling of devices has resulted in processes that require or benefit from polysilicon gate structures having a thickness of less than 1200 Angstroms. Thin polysilicon exhibits desirable etch profiles. The thickness of the silicide, however, needs to be of a minimum thickness to have its desired affect on contact resistance and to achieve desirable conductivity of the polysilicon structure. Anecdotal evidence suggests that forming a relatively thick silicide layer over a relatively thin polysilicon layer exhibits varying degrees of “silicide spiking.” Referring to FIG. 1, a semiconductor wafer 100 is shown after silicide formation. Wafer 100 includes a silicon substrate 102 over which a gate oxide 104 is formed. Polysilicon 106 is formed overlying gate oxide 104 and silicide 108 is formed on polysilicon 106. As seen in FIG. 2, a cross-sectional view of wafer 100 is illustrated prior to forming silicide 108. As illustrated in FIG. 2, polysilicon 106 exhibits crystalline grain boundaries 120 that tend to be oriented generally parallel to a direction of growth, represented by reference numeral 122, and that are typically elongated and perpendicular to the interface 105 between gate oxide 104 and polysilicon 106. When the silicide 108 is subsequently formed, as seen in FIG. 3, it frequently exhibits silicide “spikes” 130 that produce an undesirably small distance 132 between silicide 108 and gate oxide 104. It is theorized that silicide spikes 130 form because the silicide forms quickly on grains with a desirable orientation (i.e., along at least some of the grain boundaries 120.

If the polysilicon 106 is thinned due to ongoing scaling, silicide spikes 130 may extend completely through polysilicon layer 106 and touch the underlying gate oxide 104. It is generally undesirable to have silicide 108 in contact with gate oxide 104. Silicide 108 may produce localized alterations of the threshold voltage required to induce a conductive channel under the gate oxide 104. Such local variations in device characteristics are highly unpredictable and undesirable. It would be advantageous, therefore, to implement a process that permitted thin polysilicon gate electrodes and thick silicide layers without exhibiting significant silicide spiking.

### SUMMARY OF THE INVENTION

The identified objective is achieved with a semiconductor device and fabrication process according to the present invention that include forming a gate dielectric overlying a semiconductor substrate and a gate electrode overlying the gate dielectric. The gate electrode includes an interface between a first portion of the gate electrode and a second portion of the gate electrode. The first and second portions of the gate electrode may include different materials. A silicide is then formed overlying the gate electrode. The presence of the gate electrode interface substantially prevents the silicide from spiking into or through the gate electrode to encroach upon or contact the underlying gate dielectric. Forming the gate electrode may include forming a polysilicon first gate electrode layer and forming a second gate electrode layer over the polysilicon first gate electrode layer. The second gate electrode layer may include an amorphous silicon layer overlying the polysilicon first gate electrode layer. Forming the amorphous silicon layer may be achieved in situ with forming the first gate electrode layer by lowering the temperature of the deposition chamber. Forming the second gate electrode layer may include forming first and second sublayers of the second gate electrode layer, where the first sublayer and the first gate electrode layer are different. In one such embodiment, the first sublayer comprises SiGe and the second sublayer is a silicon material such as polycrystalline or amorphous silicon. In this embodiment, the SiGe layer may be formed in situ with the underlying polysilicon first gate electrode layer and the overlying polysilicon second sublayer by altering the gas flow in a deposition chamber to introduce a germanium bearing species when the SiGe layer is being formed.

### BRIEF DESCRIPTION OF THE DRAWINGS

The invention, together with further advantages thereof, may best be understood by reference to the following description taken in conjunction with the accompanying drawings in which:

FIG. 1 is a cross sectional view of a semiconductor wafer following silicide formation according to the prior art;

FIG. 2 illustrates the grain structure of the typical polysilicon layer used to form gate electrodes on the wafer of FIG. 1;

FIG. 3 illustrates silicide spikes following silicide formation in the wafer of FIG. 2;

FIG. 4 is a partial cross sectional view of a semiconductor wafer following silicide formation according to one embodiment of the present invention;

FIG. 5 is a partial cross sectional view of a portion of the wafer of FIG. 4 according to one embodiment of the invention;

FIG. 6 is a cross section view of a wafer according to the present invention following silicide formation;

FIGS. 7-9 illustrates various implementations of the wafer of FIG. 6; and

FIGS. 10-15 illustrate a sequence of processing steps according to the present invention suitable for forming the wafers of FIGS. 6-9.

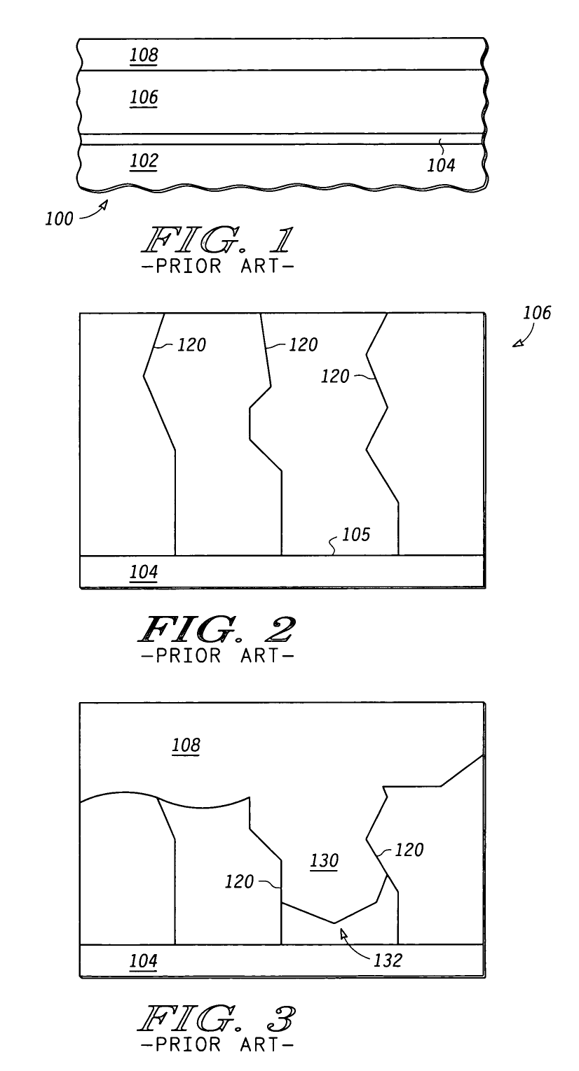

### DETAILED DESCRIPTION OF THE PREFERRED EMBODIMENTS

Reference will now be made in detail to the presently preferred embodiments of the invention, examples of which are illustrated in the accompanying drawings. It should be noted that the drawings are in simplified form and are not to precise scale. Although the invention herein refers to certain illustrated embodiments, it is to be understood that these embodiments are presented by way of example and not by way of limitation. The intent of the following detailed description is to cover all modifications, alternatives, and equivalents as may fall within the spirit and scope of the invention as defined by the appended claims.

Generally speaking, the invention is concerned with a semiconductor fabrication process that permits relatively thick silicide layers to be formed over relatively thin polysilicon gate electrodes without exhibiting silicide spikes that penetrate the polysilicon and contact the underlying gate electrode. A gate dielectric is formed overlying a semiconductor substrate and a first gate electrode layer is formed overlying the gate dielectric. The first gate electrode layer is likely a polysilicon or amorphous silicon layer. A second gate electrode layer is then formed over the first gate electrode layer where the first and second gate electrode layers are different. Like the first gate electrode layer, the second gate electrode layer may include polycrystalline or amorphous silicon. In one embodiment, the second gate electrode layer itself includes two layers. A silicon-germanium sublayer is formed on the first gate electrode layer and a polysilicon second sublayer is formed over the SiGe layer. In any of the embodiments, the grain boundaries in the polysilicon layer do not extend from the gate dielectric to the subsequently formed silicide. Instead, the polysilicon grains terminate at an interface between the first and second gate electrode layers (i.e., substantially none of the grain boundaries traverse the interface) and silicide spiking is thereby limited or prevented.

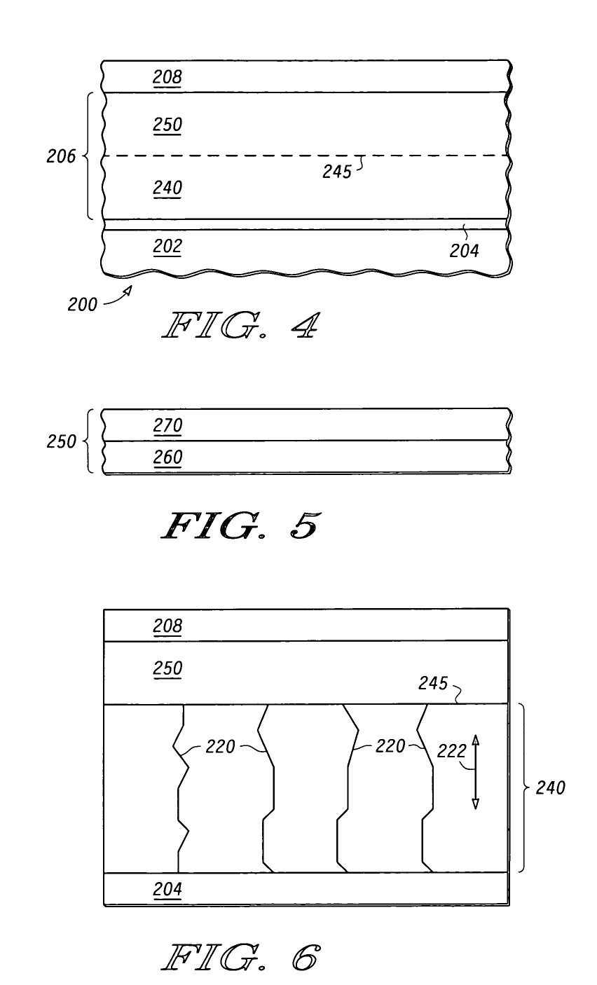

Turning now to the drawings, FIG. 4 is a partial cross sectional view of a semiconductor device 200 following the formation of a silicide layer 208 overlying a gate electrode 206 according to one embodiment of the present invention. Semiconductor device 200, as depicted in FIG. 4, is likely a portion of an integrated circuit at a stage in the fabrication process prior to the completion and interconnection of individual transistors. The portion of device 200 depicted in FIG. 4 illustrates a portion of a single transistor gate electrode and the underlying gate dielectric and substrate. In this embodiment, Device 200 includes a semiconductor substrate 202, a gate dielectric layer 204 overlying substrate 202, the gate electrode 206 overlying gate dielectric layer 204, and the silicide layer 208 overlying gate electrode 206. Substrate 202 is likely comprised of p-doped or n-doped crystalline silicon. In some embodiments, substrate 202 is a silicon-on-insulator (SOI) substrate that includes a dielectric layer (not shown) located between a bulk silicon portion (not shown) of the substrate and an active silicon portion into which the transistors are formed.

The gate dielectric 204 overlying substrate 202 may include a traditional, thermally formed silicon-oxide (e.g., SiO₂). In other embodiments, gate dielectric 204 may include a high-K dielectric, which is typically comprised of a metal-oxide compound. High K materials are desirable for their higher dielectric constant and the corresponding relaxation in gate dielectric thickness that such material permit. In the depicted embodiment, gate electrode 206 is a multi-layered structure that includes a first gate electrode layer 240 and a second gate electrode layer 250. The intersection between first and second gate electrode layers 240 and 250 is referred to herein as a boundary or interface 245. In the depicted embodiment, interface 245 is substantially parallel to an upper surface of substrate 202. Interface 245 is formed when the second gate electrode layer 250 is formed over the underlying first gate electrode layer 240. Second gate electrode layer 250 is different than first gate electrode layer 240 in at least one electrical or material characteristic. The characteristic that differentiates first and second layers 240 and 250, for example, may be the composition of the two layers, the crystalline grain structure of the two layers, the thickness of the layers, and so forth. Additional details and implementations of the structure shown in FIG. 4 as illustrated in greater detail in FIGS. 6 through 9.

In embodiments of the invention illustrated in FIG. 6, first gate electrode layer 240 is polycrystalline silicon (also referred to as polysilicon or poly). This embodiment is important for integration purposes because the transistors in any process exhibit characteristics that depend on, at least in part, the composition of the gate electrode material. Because polysilicon gate processes have been used so widely and for such a long period of time, poly gate-based processes are well characterized such that, for example, the substrate implants required to produce desired threshold voltages are generally well known. As described previously, the polysilicon first gate electrode layer 240 exhibits long, grain boundaries 220 that tend to be oriented generally parallel to a direction of growth, represented by reference numeral 222, which is typically perpendicular to the an upper surface of substrate 202. As seen in FIG. 6, the presence of second gate electrode layer 250 and interface 245 terminates the grain boundaries 220 of polysilicon first gate electrode layer 240 at the interface and thereby prevents those boundaries from traversing interface 245 and extending all the way to silicide 208 and thus limits the opportunities for silicide 208 to spike through layer 240 to contact dielectric 204. Specific implementations of this embodiment are described in greater detail below.

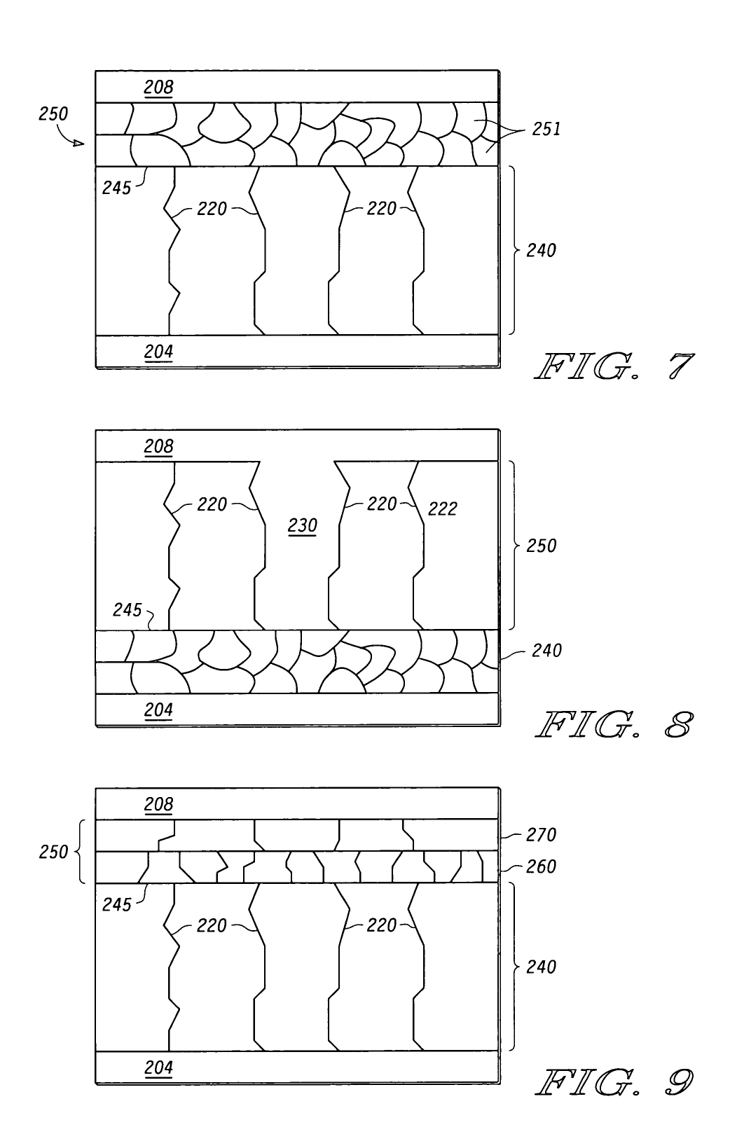

For embodiments in which first gate electrode layer 240 is polysilicon, at least a portion of second gate electrode layer 250 is a material other than polysilicon. In an embodiment depicted in greater detail in FIG. 7, for example, second gate electrode layer 250 is amorphous silicon. The amorphous silicon in second gate electrode layer 250 exhibits localized areas 251 of crystalline silicon as opposed to the relatively long and oriented grain boundaries 220 of the polysilicon in first gate electrode layer 240. In this embodiment, interface 245 between polysilicon first gate electrode layer 240 and amorphous silicon second gate electrode layer 250 represents the discontinuities between the grain boundaries in first gate electrode layer 240 and the grain boundaries in second gate electrode layer 250. The grain boundaries 220 in polysilicon first gate electrode layer 250 do not extend between the gate electrode underlying the polysilicon and the silicide layer 208. Instead, polysilicon grain boundaries 220 of polysilicon first gate electrode layer 240 terminate at the interface 245 with amorphous silicon second gate electrode layer 250.

In an alternative implementation of the amorphous silicon/polysilicon embodiment described above, first gate electrode layer 240 is amorphous silicon and second gate electrode layer 250 is polysilicon as depicted in FIG. 8. The interface 245 in this embodiment still prevents the polysilicon grain boundaries 220 from extending between silicide 208 and gate dielectric 204, but in this case, polysilicon grain boundaries 220 extend from the silicide 208 to interface 245. Although silicide spiking may occur (as indicated by the silicide spike 230) due to the presence of properly oriented grain boundaries 220 in contact with silicide 208, any such spiking would terminate at the interface 245 and thereby be prevented from encroaching upon or contacting gate dielectric 204.

Some embodiments of device 200 may use a second gate electrode layer 250 that itself includes two or more sublayers. In such an embodiment, second gate electrode layer 250 includes a second sublayer 270 overlying a first sublayer 260. This embodiment may be useful, as an example, in an application where it is desirable to use the same material for first gate electrode layer 240 and second sublayer 270. As described above, using polysilicon for first gate electrode layer 240 is advantageous because of its well characterized properties as a gate electrode. It may also be desirable to be able to form silicide 208 on polysilicon because of more desirable electrical properties of the resulting silicide. In such cases, the embodiment depicted in FIG. 5 provides a process that may use polysilicon as first gate electrode layer 240 and second sublayer 270 while still providing protection against silicide spiking. This embodiment of device 200 is depicted in greater detail in FIG. 9. The use first sublayer 260 intermediate between polysilicon first gate electrode layer 240 and polysilicon second sublayer 270 effectively serves to terminate the grain boundaries of both polysilicon layers such that there is no grain boundary path extending from silicide 208 to gate dielectric 204.

In the embodiment depicted in FIG. 9, first sublayer 260 is likely a silicon-containing semiconductor such as SiGe. SiGe is a good candidate for first sublayer 260 because (1) it can be deposited in situ with either amorphous or polycrystalline silicon and it exhibits acceptable electrical conductivity characteristics. As depicted in FIG. 9 the SiGe first sublayer 260 deposits as a polycrystalline film that terminates the grain boundaries of the underlying polysilicon first gate electrode layer 240. In other variations of the embodiment depicted in FIG. 9, first gate electrode layer 240 and second sublayer 270 may both be amorphous silicon, first gate electrode layer 240 may be amorphous and second sublayer 270 polycrystalline, or vice versa.

Turning now to FIGS. 10 through 15, a sequence of partial cross sectional views is depicted to illustrate a process of fabricating the semiconductor device 200 of FIG. 4. In FIG. 10, gate dielectric layer 204 is formed on an upper surface of semiconductor substrate 202. Gate dielectric layer 204 may comprises a silicon-oxide such as SiO₂ formed by exposing substrate 202 to an oxygen bearing ambient at a temperature in the range of approximately 800 to 1200° C. In other embodiments, gate dielectric is formed by depositing a metal-oxide compound, such as HfO₂, having a dielectric constant that is greater than approximately 4.0. In the case of thermally formed silicon-oxide, the thickness of gate dielectric layer 204 is in the range of 5 to 100 angstroms. In the case of a high-K dielectric, the thickness may be scaled to achieve an equivalent oxide thickness of 5 to 100 angstroms where equivalent thickness is determined by the actual thickness divided by the dielectric constant.

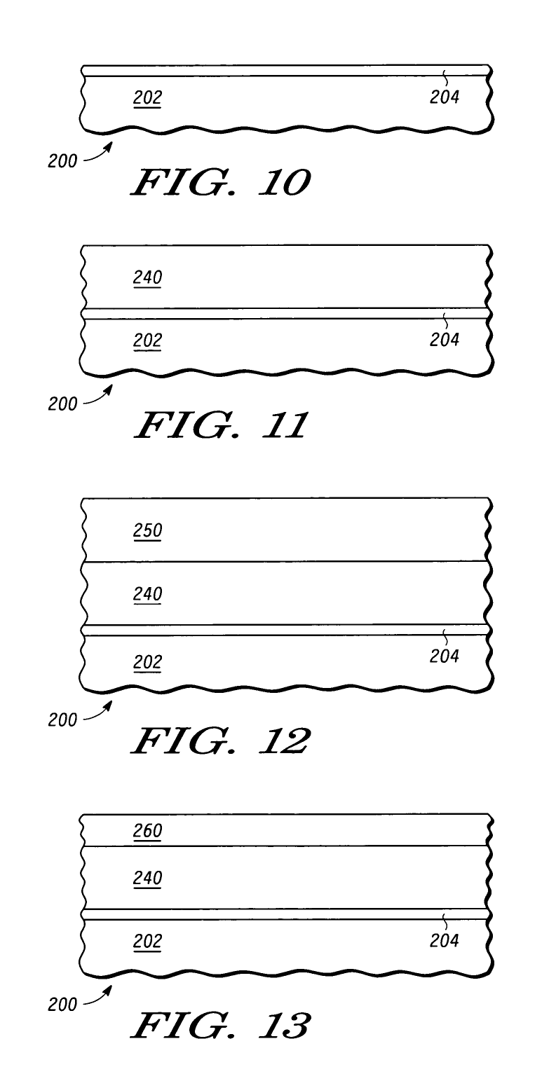

As depicted in FIG. 11, first gate electrode layer 240 is then deposited over gate dielectric 204. In an embodiment in which first gate electrode layer 240 is polysilicon, the polysilicon deposition may be achieved by thermally decomposition of silane in a deposition chamber maintained at a temperature in the range of approximately 600 to 650° C. For embodiments in which first gate electrode layer 240 is amorphous silicon the deposition temperature is generally less than 580° C. The thickness of first gate electrode layer 240 is preferably in the range of approximately 100 to 500 angstroms.

FIG. 12 shows a processing step subsequent to FIG. 13 in which the second gate electrode layer 250 is a single layer. In this embodiment, second gate electrode layer is preferably either amorphous silicon or polysilicon depending upon the composition of first gate electrode layer 240. If first gate electrode layer 240 is polysilicon, then second polysilicon layer is amorphous silicon and vice versa. In either case, the second gate electrode layer 250 is preferably deposited in situ with the deposition of first gate electrode layer 240 and the transition from polysilicon to amorphous silicon or vice versa is achieved by changing the deposition temperature. In either embodiment, second gate electrode layer 250 preferably has a thickness in the range of approximately 300 to 700 angstroms.

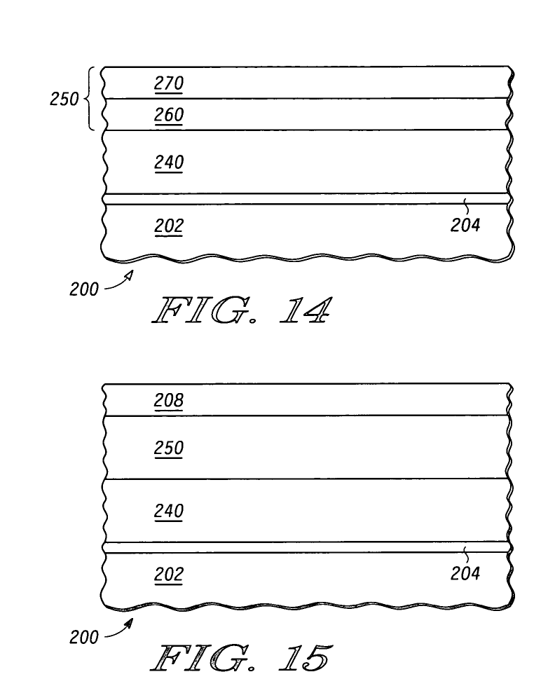

Turning to FIGS. 13 and 14, a processing sequence alternative to the processing depicted in FIG. 12 is performed to provide a second gate electrode layer 250 having a first sublayer 260 and a second sublayer 270. In one such implementation, first gate electrode layer 240 is polysilicon and first sublayer 260 is formed in situ with the formation of first gate electrode layer 240 by altering the gas flows after first gate electrode layer 240 has achieved a desired thickness. More specifically, the formation of first sublayer 260 is achieved by introducing a germanium bearing species into the deposition chamber following the completion of first gate electrode layer 240. In one such implementation, all other deposition parameters are maintained to simplify the manufacturing process. When the SiGe first sublayer 260 has achieved a desired thickness, preferably in the range of approximately 100 to 300 angstroms, the germanium species is turned off and the second sublayer 270 is formed overlying SiGe first sublayer 260. In one embodiment, a preferable thickness of second sublayer 270 is in the range of approximately 200 to 400 angstroms. Depending upon the deposition parameters, especially the deposition temperature, first gate electrode layer 240 and second sublayer 270 will either both be polysilicon or both be amorphous silicon.

Turning now to FIG. 15, silicide 208 is formed overlying second gate electrode layer 250. It will be appreciated that, in a likely embodiment, additional processing (not shown) has been performed prior to forming silicide 208. Specifically, the gate electrode structure has likely been patterned to form transistors gates, source/drain regions have been formed by implanting a p-type or n-type dopant into substrate 202 using the pattered gate electrodes as an implant mask, and dielectric spacers have been formed on sidewalls of the patterned gate electrodes. Following such processing, a silicide step is performed to form silicide 208, not only overlying the second gate electrode layer 250, but also overlying the exposed source/drain regions.

Silicide 208 is formed by depositing a metallic element such as cobalt over the entire wafer and exposing the wafer to a temperature in the range of approximately 400 to 600° C. to form a CoSi₂ silicide 208 where the cobalt contacts exposed silicon. Everywhere else (i.e., where the cobalt contacts a dielectric), the deposited cobalt will remain unreacted following the heat step and can be removed with an etch process that exhibits good selectivity of the unreacted cobalt with respect to both the silicide and the dielectric. In the preferred implementation, the thickness of silicide 208 is in the range of 100 to 500 angstroms. Following the formation of silicide 208, back end processing (not depicted) is performed to interconnect the transistors and other elements of device 200 as is well known in the field of integrated circuit manufacturing. The use of a gate electrode containing an internal interface or microstructure that prevents suicide to gate dielectric grain boundaries beneficially enables the desirable reduction in polysilicon thickness without risking substantial silicide spiking.

It is to be understood and appreciated that the process steps and structures described herein do not cover a complete process flow for the manufacture of an integrated circuit. The present invention may be practiced in conjunction with various integrated circuit fabrication techniques that are conventionally used in the art, and only so much of the commonly practiced process steps are included herein as are necessary to provide an understanding of the present invention.

Thus it will apparent to those skilled in the art having the benefit of this disclosure that there has been provided, in accordance with the invention, a process for fabricating a an integrated circuit that achieves the advantages set forth above. Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications as fall within the scope of the appended claims and equivalents thereof.

1. A semiconductor fabrication process, comprising:
forming a gate dielectric overlying a semiconductor substrate;
forming a gate electrode by:
depositing a first gate electrode layer in contact with the gate dielectric, wherein the first gate electrode layer is selected from the group consisting of polysilicon and amorphous silicon;
depositing a silicon germanium layer in contact with the first gate electrode layer; and
depositing a third gate electrode layer in contact with the silicon germanium layer, wherein the third gate electrode layer material is the same as the first gate electrode material; and
forming a silicide in contact with the third gate electrode.

2. The method of claim 1, wherein depositing the first and third gate electrode layers comprises depositing a polysilicon layer at a temperature in the range of approximately 600 to 650 C.

3. The method of claim 1, wherein depositing the first and third gate electrode layers comprises depositing an amorphous silicon layer at a temperature of less than approximately 580 C.

4. The method of claim 1, wherein forming the third gate electrode layer comprises forming the third gate electrode layer in situ with forming the first gate electrode layer by lowering the temperature of the deposition chamber.

5. (canceled)

6. The method of claim 1, wherein the SiGe comprises polycrystalline SiGe.

7. The method of claim 6, wherein forming the second gate electrode layer is achieved in situ by introducing a germanium bearing species into a deposition chamber after forming the first gate electrode layer.

8. A semiconductor device, comprising:
a gate dielectric overlying a semiconductor substrate;
a gate electrode comprising a first gate electrode layer in contact with a second gate electrode layer wherein the first gate electrode layer contacts the gate dielectric and wherein the first and second gate electrode layers are both selected from the group consisting of polysilicon and amorphous silicon and wherein the first and second gate electrode layers differ; and
a silicide in contact with the second layer.

9. The device of claim 8, wherein the gate electrode includes:
a polysilicon first gate electrode layer; and
an amorphous silicon second gate electrode layer.

10. The device of claim 8, wherein the first gate electrode layer is an amorphous silicon layer and wherein the second gate electrode layer is a polysilicon layer.

11-12. (canceled)

13. The device of claim 8, wherein the first gate electrode layer is an amorphous silicon layer and wherein the second gate electrode layer is a polycrystalline silicon layer.

14. The device of claim 8, wherein the silicide comprises CoSi₂.

15. A semiconductor fabrication process, comprising:
forming a gate electrode overlying a gate dielectric layer overlying a semiconductor substrate, wherein the gate electrode includes first and second layers in contact with one another wherein the first layer contacts the gate electrode;
wherein at least one of the first and second layers includes polycrystalline silicon; and
forming a silicide in contact with the second gate electrode layer.

16. (canceled)

17. The process of claim 15, wherein the first gate electrode layer comprises polycrystalline silicon and wherein the second gate electrode layer comprises amorphous silicon.

18. The process of claim 15, wherein the first gate electrode layer comprises amorphous silicon and wherein the second gate electrode layer comprises polycrystalline silicon.

19. (canceled)

20. The process of claim 15, wherein forming the silicide comprises forming a CoSi₂ silicide.
